(19) United States
(12) Patent Application Publication
(10) Pub. No.: US 2025/0196491 A1
(43) Pub. Date: Jun. 19, 2025

(54) CONTROLLED DELAMINATION THROUGH SURFACE ENGINEERING FOR NONPLANAR FABRICATION

(71) Applicant: Massachusetts Institute of Technology, Cambridge, MA (US)

(72) Inventors: Farnaz Niroui, Cambridge, MA (US); Sarah O. Spector, Cambridge, MA (US); Peter Franklin Satterthwaite, Cambridge, MA (US)

(21) Appl. No.: 18/845,794

(22) PCT Filed: Mar. 23, 2023
(86) PCT No.: PCT/US2023/016143

§ 371 Date: Sep. 10, 2024

Related U.S. Application Data
(60) Provisional application No. 63/323,372, filed on Mar. 24, 2022.
(60) Provisional application No. 63/347,737, filed on Jun. 1, 2022.

(51) Int. Cl. B32B 43/00

(52) U.S. Cl. CPC B32B 43/006

(57) ABSTRACT

A method of forming nonplanar nanostructures on a substrate is disclosed. The method includes treating a portion of the surface of the substrate so as to affect its properties. A film is then applied to the substrate after the surface engineering has been completed. Energy is then applied to the film, causing it to delaminate in the regions where the surface was treated, thereby creating the nonplanar nanostructures. The surface treatment may include the application of a self-assembled molecular (SAM) layer, which includes an anchoring group that allows assembly on the surface of the substrate, and also has a functional group that has the desired interaction with the film. The nonplanar nanostructures may be used to form nanoswitches, resonators, and strain engineered surfaces.

This application claims priority to U.S. Provisional Patent Application Ser. No. 63/323,372, filed Mar. 24, 2022 and U.S. Provisional Patent Application Ser. No. 63/374,737, filed Sep. 6, 2022, the disclosures of which are incorporated by reference in their entireties.

### FIELD

This disclosure describes a system and method for nonplanar nanostructure fabrication by controlled delamination through surface engineering.

### BACKGROUND

Nonplanar nanostructures, which are made up of suspended ultrathin films and nanogaps, are required for next generation miniaturized nanoelectromechanical systems (NEMS), photonic elements, metamaterials and other devices. However, these structures suffer from instabilities that are caused by van der Waals and capillary forces, which become increasingly dominant at the nanoscale. These forces may make it difficult to perform nonplanar fabrication through conventional top-down techniques, which often require the application and subsequent removal of a sacrificial support layer. The instabilities involved in this process become more prominent as dimensions reduce to the few-nanometers regime, resulting in low process yield. Smaller device sizes are needed for improved device efficiency, speed, sensitivity, and the creation of new functionality.

Various techniques are currently used to fabricate these three-dimensional nanostructures beyond the conventional sacrificial layer approach. These include additive manufacturing using electron- and ion-beam induced processes, two-photon lithography, and kirigami. However, each of these approaches is typically limited to features that are greater than 100 nm. These structures are often not mechanically-active, and are largely incompatible with conventional wafer-scale processes.

Thus, it would be beneficial to overcome the inherent limits of top-down strategies to allow the development of nonplanar designs at small dimensions. Further, it would be advantageous if the system and method allows nanostructures of different dimensions to be predictably fabricated with spatial control.

### SUMMARY

A method of forming nonplanar nanostructures on a substrate is disclosed. The method includes treating a portion of the surface of the substrate so as to affect its properties. A film is then applied to the substrate after the surface engineering has been completed. Energy is then applied to the film, causing it to delaminate in the regions where the surface was treated, thereby creating the nonplanar nanostructures. The surface treatment may include the application of a self-assembled molecular (SAM) layer, which includes an anchoring group that allows assembly on the surface of the substrate, and also has a functional group that has the desired interaction with the film. The nonplanar nanostructures may be used to form nanoswitches, resonators, sensors, actuators, active matter, and strain engineered surfaces. There are also other applications of these nonplanar nanostructures.

According to one embodiment, a method of surface engineering is disclosed. The method comprises treating a portion of a surface of a substrate to produce an engineered surface; applying a film over the engineered surface; and applying energy to induce delamination of the film from the engineered surface so as to form a nonplanar nanostructure. In some embodiments, the substrate comprises silicon. In some embodiments, the substrate comprises an oxide, a nitride or a metallic material. In some embodiments, treating a portion of the surface comprises applying a self-assembled molecular (SAM) layer to the portion of the surface. In some embodiments, treating a portion of the surface comprises applying a patterned mask to the surface; depositing a self-assembled molecular (SAM) layer to the surface after application of the patterned mask; and removing the patterned mask after depositing the SAM layer. In some embodiments, the SAM layer comprises (3-Aminopropyl)triethoxysilane (APTES). In some embodiments, the molecules in the SAM layer have an anchoring group and a functional group; and the anchoring group is a silane group, an OH group, an COOH group or a thiol group and the functional group is an amine group, a hydroxyl group or a carboxyl group. In some embodiments, the film comprises an oxide. In certain embodiments, the film comprises Al₂O₃ or HfO₂. In some embodiments, the film has a thickness of between 2 and 40 nm. In some embodiments, the film is applied using atomic layer deposition. In some embodiments, the applied energy is light, heat or an electron beam. In some embodiments, the nonplanar nanostructure is a dome shaped nanostructure, and the method further comprising applying a second mask to portions of the dome shaped nanostructure; and removing the film in exposed regions so as to form a bridge structure.

In some embodiments, the film comprises a plurality of layers. In certain embodiments, one of the plurality of layers comprises a metal layer. In certain embodiments, the metal layer is a partial layer. In some embodiments, a first layer comprises an oxide and a second layer, disposed on the first layer, comprises a two-dimensional material. In certain embodiments, the second layer is conformally adhered to the first layer. In some embodiments, the delamination induces strain in the two-dimensional material. In some embodiments, the strain changes optical and/or electrical properties of the two-dimensional material. In some embodiments, the method further comprises applying an external stimulus to the nonplanar nanostructure to reduce or tune the strain. In some embodiments, the external stimulus is actively modulated. In some embodiments, the external stimulus is electrostatic, mechanical, thermal, or piezoelectric.

According to another embodiment, a resonator is disclosed. The resonator comprises a film formed in a bridge structure, having two ends that contact the substrate and a middle portion suspended above the substrate by a gap; wherein the gap is between 5 nm and 5 um. In some embodiments, the film comprises an Al₂O₃ or HfO₂. In some embodiments, the film comprises a plurality of layers. In certain embodiments, a first layer comprises an oxide layer. In certain embodiments, a second layer comprises a metal. In certain embodiments, a second layer is a partial layer that does not cover an entirety of a first layer. In some embodiments, a metal layer is disposed on the substrate beneath the gap.

According to another embodiment, an electronic device is disclosed, wherein the electronic device comprises a nonplanar nanostructure formed using the method described above.

According to another embodiment, a nonplanar nanostructure is disclosed. The nonplanar nanostructure is formed on a substrate and comprises a film in a form of a dome shaped blister, wherein a middle portion of the blister is suspended above the substrate by a gap; wherein the gap is between 5 nm and 5 μm. In some embodiments, the film comprises an Al₂O₃ or HfO₂. In some embodiments, the film comprises a plurality of layers. In certain embodiments, a first layer comprises an oxide layer. In certain embodiments, a second layer comprises a metal. In certain embodiments, a second layer is a partial layer that does not cover an entirety of a first layer. In some embodiments, a metal layer is disposed on the substrate beneath the gap. In some embodiments, a second layer comprises a two dimensional material. In certain embodiments, the two dimensional material is a transition metal dichalcogenide.

### BRIEF DESCRIPTION OF THE DRAWINGS

For a better understanding of the present disclosure, reference is made to the accompanying drawings, in which like elements are referenced with like numerals, and in which:

FIGS. 1A-1F shows a substrate as it undergoes the process to create a nonplanar nanostructure;

FIG. 2 shows a cross-sectional scanning electron micrograph of one embodiment of the nonplanar nanostructure created using the process shown in FIGS. 1A-1F;

FIGS. 3A-3B show the relationship between different parameters;

FIG. 4 shows the relationship between blister diameter and SAM region area as a function of film thickness;

FIGS. 5A-5B show additional fabrication processes that may be used to create a resonator;

FIGS. 6A-6E show the bridge structures and their properties;

FIG. 7A-7C shows various enhancements that may be made to the process shown in FIGS. 1A-1F;

FIG. 8 shows a photoluminescence (PL) map of monolayer MoS2 on a textured surface;

FIGS. 9A-9B show graphs showing the photoluminescence of MoS2 at various points along the nanostructure;

FIGS. 10A-10D show the Raman shifts for the MoS2 nanostructures; and

FIGS. 11A-11B show graphs showing the photoluminescence of WSe2 at various points along the nanostructure.

### DETAILED DESCRIPTION

The present disclosure describes an approach in which nonplanar nanostructures may be fabricated using planar processes enhanced with surface engineering, which may be used to deterministically induce controlled, selective delamination of two adjacent surfaces.

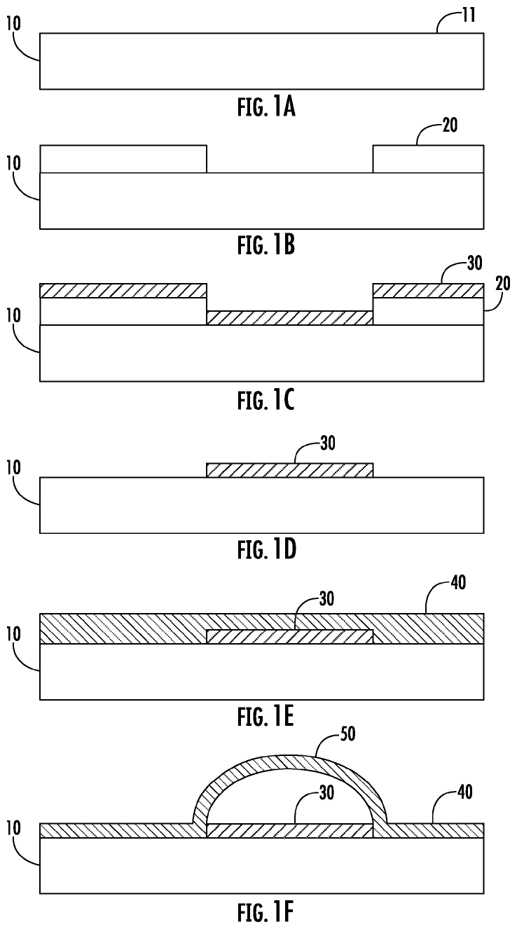

FIGS. 1A-1F show a process that a substrate may undergo to create a nonplanar nanostructure. As shown in FIG. 1A, the process begins with a substrate 10. The substrate may be any material which can support surface modification and subsequent thin-film deposition. The substrate 10 may be any suitable material, such as silicon. Additionally, the substrate 10 may be a nitride, oxide or metallic substrate. For example, substrates such as silicon oxide, aluminum oxide, silicon nitride, tungsten and hafnium oxide (HfO₂) may be utilized. The substrate 10 has a surface 11, upon which the nonplanar nanostructure will be fabricated.

First, as shown in FIG. 1B, a mask 20 is applied to portions of the surface 11. The mask 20 may be any suitable material that is conventionally used in semiconductor processing. Further, the mask 20 may be patterned using lithography, as is well known. In some embodiments, the mask 20 may be a polymer resist mask. In other embodiments, the mask 20 may be a hard mask, such as an Al₂O₃ hard mask or a hard mask made using any suitable material.

In one particular embodiment, the mask 20 is a Al₂O₃ hard mask that is patterned using a positive photoresist. In this embodiment, a Al₂O₃ layer is created using atomic layer deposition (ALD), which is used to create an Al₂O₃ layer having a thickness of 1-5 nm. After, a positive photoresist may be lithographically patterned on top of the Al₂O₃ layer and developed using tetramethylammonium hydroxide (TMAH) developer. During development, the exposed Al₂O₃ layer is also etched by the TMAH developer, thereby allowing the Al₂O₃ to be patterned as well. The photoresist may then be removed using acetone, leaving the patterned Al₂O₃ hard mask. This technique may be beneficial in that the photoresist is never in contact with the surface 11 of the substrate 10. In some embodiments, the patterns may comprise one or more circles or squares. While this embodiment describes a hard mask made using a positive photoresist, other embodiments are also possible. For example, the hard mask may utilize a negative photoresist material. In another embodiment, the mask may be constructed using an electron-beam resist rather than a photoresist.

Next, the surface 11 of the substrate 10 is treated to form an engineered surface. In one embodiment, shown in FIG. 1C, the self-assembled molecular (SAM) layer 30 is deposited in vapor or liquid phase on the surface 11 of the substrate 10. The SAM layer 30 includes a monolayer molecular assembly formed on the surface by chemisorption, constituted by any molecule having an anchoring group that allows assembly on the surface 11 of the substrate 10, and also has a functional group that has the desired interaction with the film 40, which is to be applied later. For substrates that are silicon, an oxide or a nitride, the SAM layer may include a silane anchoring group. For tungsten, silicon, SiO₂ and HfO₂, the anchoring groups may also be an OH group or a COOH group. In some embodiments, the functional group may be an amine group. In other embodiments, the functional group may be a hydroxyl or carboxyl group. In certain embodiments, (3-Aminopropyl)triethoxysilane (APTES) is used as the SAM layer 30. SAM layers with alternative properties may be used alongside different substrate materials, such as a thiol anchoring group for a gold substrate or a platinum substrate. The areas of the surface 11 on which the SAM layer 30 is directly deposited may be referred to as SAM regions. The size and shape of the SAM regions is determined based on the patterning of the mask 20. The SAM regions represent engineered surfaces.

After the SAM layer 30 has been assembled, the mask 20 is removed, as shown in FIG. 1D. In one embodiment using an Al₂O₃ hard mask, this may be done by using a TMAH solution to remove the mask 20. In one embodiment using a polymeric mask, this may be done using a solvent such as acetone.

Next, as shown in FIG. 1E, a film 40 is applied to the surface 11 of the substrate 10. The film 40 may be any material that may be grown, transferred or deposited on the substrate 10. In some embodiments, the film 40 may be applied using ALD, and may have a thickness of 2-40 nm. In certain embodiments, the film 40 may be an oxide, such as Al₂O₃. In some embodiments, the film 40 may be HfO₂. Further, in certain embodiments, the film 40 may comprise a plurality of layers. For example, in certain embodiments, one of the layers may be a metal layer. In another embodiment, one of the layers may be a two-dimensional material. A two-dimensional material is a crystalline solid that forms in layers, wherein each layer is typically one to three atoms in thickness.

Next, an external stimulus, in the form of an applied energy, is used to create the nonplanar nanostructures 50, as shown in FIG. 1F. In certain embodiments, the energy may be in the form of heat. For example, the assembly shown in FIG. 1E may be subjected to an anneal at an elevated temperature, such as greater than 400° C. In other embodiments, the applied energy may be light energy or an electron beam. The applied energy causes the film 40 in the vicinity of the SAM regions to be lifted from the surface 11 of the substrate 10 to create the nonplanar nanostructure 50. In some embodiments, the gap between the surface 11 of the substrate and the nonplanar nanostructure may be between 7 and 800 nm. In some embodiments, the gap may be between 5 nm and 2 μm. In certain embodiments, the gap may be between 5 nm and 5 μm. This gap defines the height of the nonplanar nanostructure 50.

In certain embodiments, the SAM regions are circular, such that the nonplanar nanostructures resemble blisters, each having a dome shape. These blisters may range in diameter from 50 nm to tens of microns, depending on the dimension of the SAM regions.

While FIGS. 1B-1D show the use of a mask to apply the SAM layer 30 to the desired sites, other methods are also possible. For example, patterning etching may be used, where the SAM layer 30 is applied to the entire surface and select portions are then etched. Alternatively, the SAM layer 30 may be contact printed.

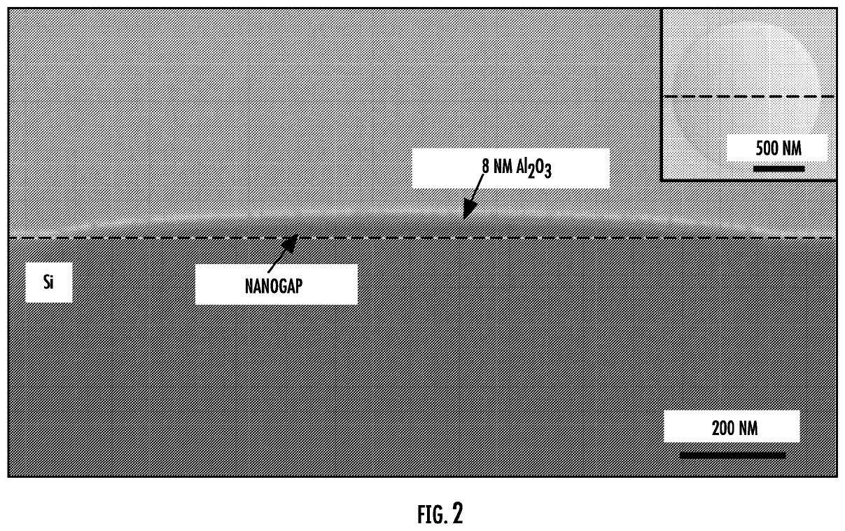

FIG. 2 shows a cross-sectional scanning electron micrograph of a nonplanar nanostructure fabricated using the process described in FIGS. 1A-1F. In this embodiment, the substrate 10 is silicon and the film 40 is Al₂O₃. The film 40 is 8 mm thick. FIG. 2 shows a clear gap between the substrate 10 and the film 40.

Thus, by applying surface engineering to a portion of the surface 11 of a substrate 10, a nonplanar nanostructure 50 may be created. The surface engineering comprises applying a surface modification to a portion of the surface 11 of the substrate 10. This surface modification may provide a low-adhesion property to the surface 11 of the substrate 10, facilitating the delamination of the film 40 during the energy application process. Thus, the surface engineering facilitates deterministically induced controlled delamination of two adjacent surfaces.

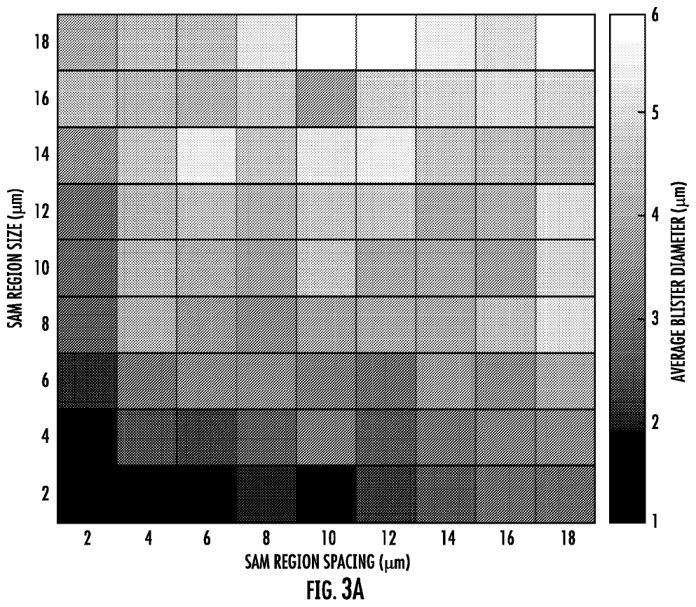

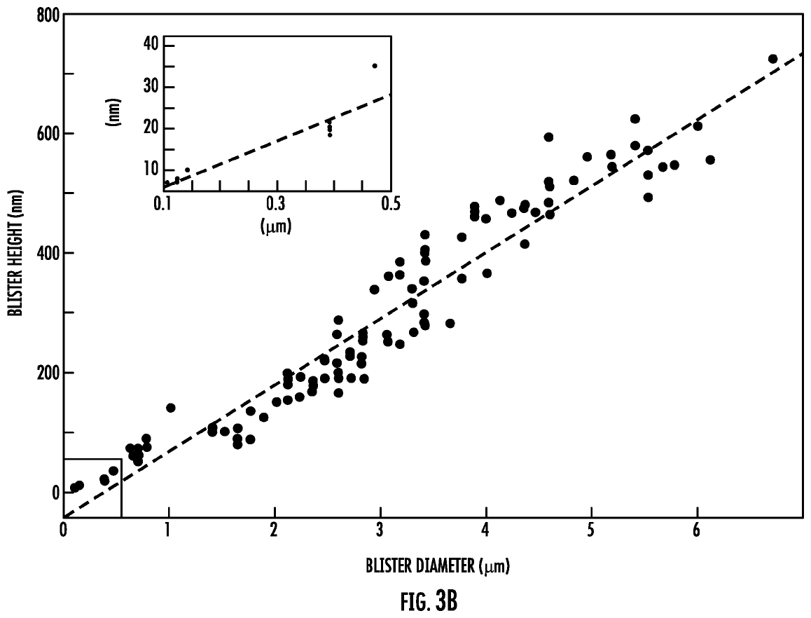

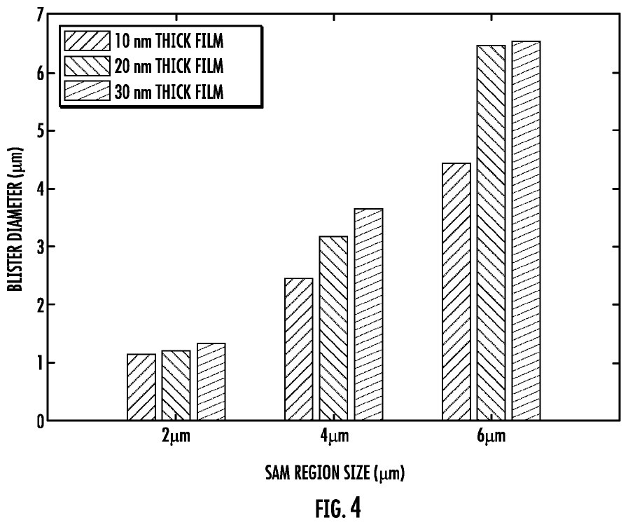

The process described above may be customized to achieve varying dimensions of the nonplanar nanostructure 50. The terms “nonplanar nanostructure” and “blister” are used interchangeably herein. For example, the dimensions of the area of the surface 11 on which the SAM layer is directly applied may help determine the final size of the nonplanar nanostructure. FIG. 3A shows the results of one experiment, where the size of SAM regions (vertical axis) and the spacing between them (horizontal axis) is varied based on the design of the lithographic mask, and the resultant diameter of the blister is measured. As a general trend, greater spacing between SAM regions results in larger diameter nonplanar nanostructures. Similarly, generally, larger diameter SAM regions also result in larger diameter nonplanar nanostructures. Additionally, the diameter of the blister determines the gap distance between the surface 11 and the film 40 after delamination. FIG. 3B shows the results of one experiment, which shows a nearly linear relationship between the diameter of the blister (horizontal axis) and the gap height (vertical axis). In some embodiments, the gap is roughly 1/10 of the diameter of the blister.

Alternatively or additionally, the dimensions of the nonplanar nanostructure 50 may be tuned by varying the thickness of the film 40 and the temperature used to induce the delamination. Specifically, in some embodiments, thicker films may result in larger nonplanar nanostructures forming more readily at lower temperatures. Conversely, thinner films require higher temperatures to form nonplanar nanostructures, and the resulting nanostructures may be smaller. The dependence of blister diameter on film thickness, based on the results of one experiment, is demonstrated in FIG. 4, where the trend shows that thicker films produce larger dome features for a given SAM region size.

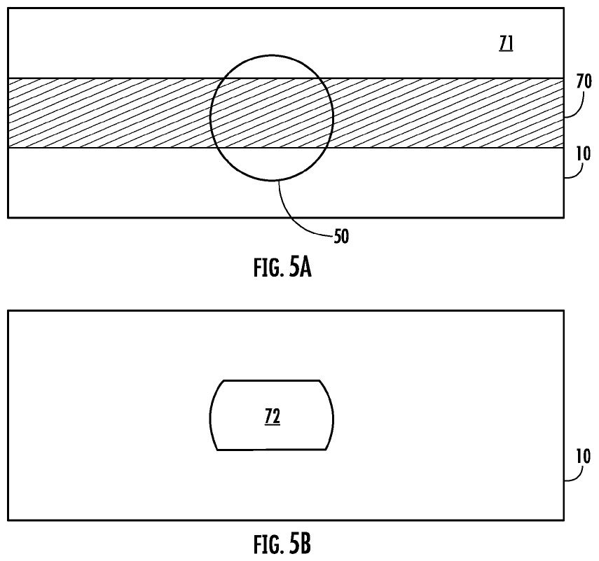

While the previous disclosure and figures show nanostructures that are in the shape of dome shaped blisters, other embodiments are also possible. For example, in one embodiment, after the process shown in FIG. 1F is completed, the film 40 is then patterned using a mask 70, as shown in FIG. 5A. In one embodiment, the mask may be a polymethylmethacrylate (PMMA) resist and may be patterned using electron beam lithography. The exposed portions 71 of the film 40 are then etched or otherwise removed. In one embodiment, this may be performed using reactive ion etching. In some embodiments, the exposed portions of the film 40 are such that only a strip 72 of the nonplanar nanostructure 50 remains. The mask 70 is then removed, as is shown in FIG. 5B. In one embodiment, this may be done using acetone. This results in a nonplanar nanostructure that is a bridge structure. The bridge structure has two opposite ends that are attached to the substrate and a middle portion that is suspended above the substrate 10 by a gap. This gap may be between 5 nm and 5 μm. In some embodiments, the gap may be between 5 nm and 2 μm. Depending on the size of the bridge, the fundamental vibrational resonant frequency may be in the range from low MHz for larger bridge structures to low GHz for smaller bridge structures.

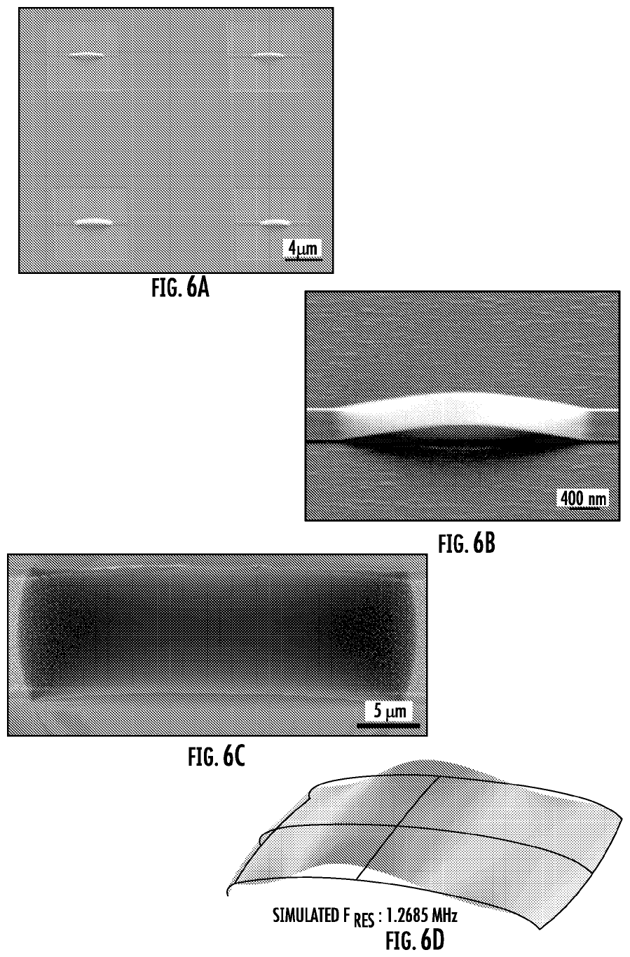

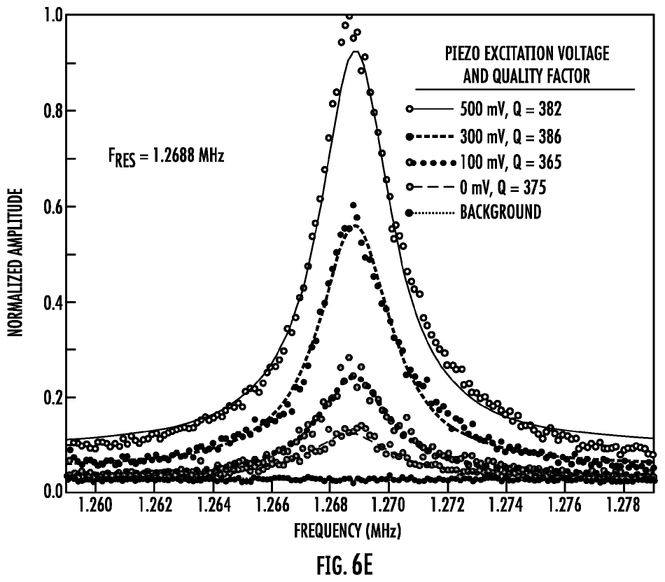

FIG. 6A-6C each show scanning electron micrographs of bridge structures made of an Al₂O₃ thin film fabricated by performing the additional process shown in FIG. 5A-5B. FIG. 6A shows a plurality of bridge structures fabricated on the same substrate. FIG. 6B shows a 2 μm×0.5 μm bridge structure fabricated as described above. FIG. 6C shows a 35 μm×10 μm bridge structure fabricated as described above. Thus, the dimension of the bridge is not limited by this approach. These bridge structures may serve as mechanical resonators.

A simulation of the bridge structure shown in FIG. 6C was then performed, which indicated that the bridge structure had a resonant frequency of about 1.2685 MHz, as shown in FIG. 6D. Finally, the fabricated device was excited using a piezo stage and its mechanical frequency response was measured using a laser interferometer. FIG. 6E represents a plot of the resonant response for various excitation amplitudes. Greater piezo excitation voltages result in greater amplitudes. This graph demonstrates a resonant frequency of 1.2688 MHz, in good agreement with simulation, suggesting that the resonator may have low built-in stress.

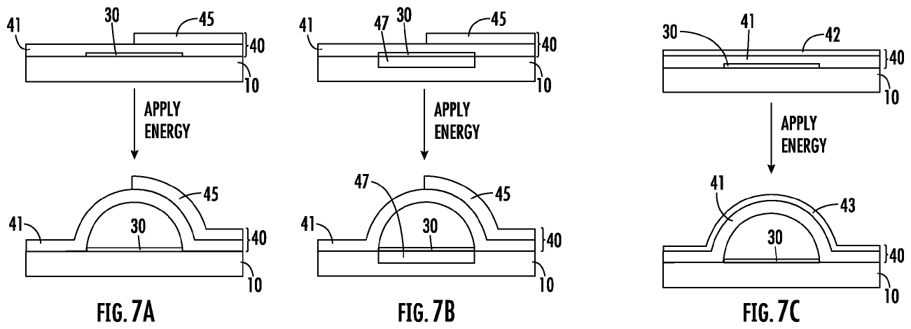

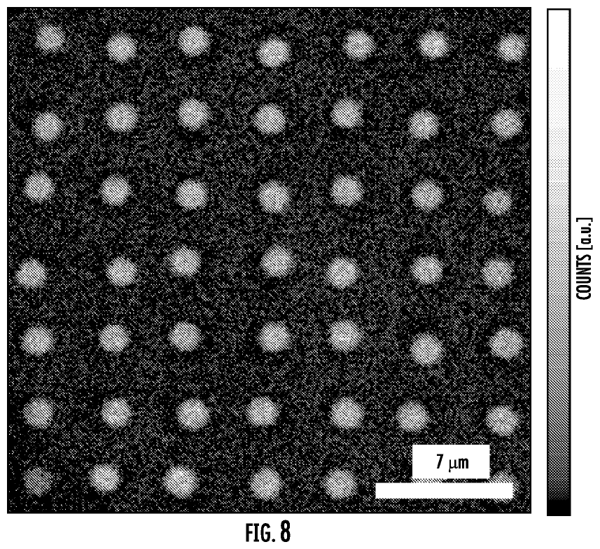

As noted above, the film 40 may include a plurality of layers. FIGS. 7A-7C show various enhancements to the process shown in FIGS. 1A-1F, which enable additional functionality.

For example, conductive layers may be included above and/or below the nanostructure to act as electrodes, enabling the electrostatic actuation of the structure In FIG. 7A, the film 40 includes a first layer 41, which may be an oxide layer, for example. The film 40 also includes a second layer 45, which may be a metal, such as aluminum, gold, tungsten, or another material. In some embodiments, the second layer 45 may be a partial layer, indicating that it does not cover the entirety of the first layer 41. For example, a mask may be applied prior to the deposition of the second layer 45, such that the second layer 45 is not disposed on the entirety of the first layer 41. In an application requiring electrostatic actuation of the nanogap, such as for a resonator or switch, a voltage may be applied between second layer 45 and the substrate 10.

Some applications may require separate top and bottom electrodes for each device to make them individually addressable. In this case, conductive layers may be patterned both above and below the nanostructure. In FIG. 7B, after application of the mask and prior to depositing the SAM layer 30, a metal layer 47 may be deposited on the substrate 10. In some embodiments, the substrate 10 may be etched to create a cavity into which the metal layer 47 will be deposited. In some embodiments, the anchoring group of the SAM layer 30 may be selected according to the material used for metal layer 47, for example, a silane anchoring group for a tungsten or aluminum layer, or a thiol anchoring group for a gold layer. In this embodiment, the film 40 may be similar to that shown in FIG. 5A, and may include a first layer 41 and a second layer 45, which may be a partial layer. A voltage may be applied between second layer 45 and metal layer 47 to actuate the nanostructure electrically as a resonator, switch, or for another purpose.

The process shown in FIG. 1A-1F may also be used for strain engineering. For example, as shown in FIG. 7C, the film 40 includes a first layer 41, which may be an oxide layer, for example. Suitable materials include Al₂O₃ and HfO₂. The film 40 also includes a second layer 42, which is directly grown, deposited or transferred on top of the first layer 41. This second layer 42 may be a two-dimensional material, such as graphene, hexagonal boron nitride or a transition metal dichalcogenide. Due to the low dimensional, quantum-confined nature of this class of materials, their electronic and optical properties, including carrier mobility and photoluminescence or electroluminescence emission, may be precisely tuned by applied strain. In other embodiments, the second layer 42 may be a thin-film bulk material or one-dimensional material such as a nanowire or carbon nanotube. Importantly, the second layer 42 is applied to the substrate 10 prior to the formation of the nonplanar nanostructures 50. The second layer 42 may be conformally adhered to the first layer 41, leading to higher or more well-controlled strain.

In this embodiment, one or a plurality of nonplanar nanostructures may be created on the substrate 10 to create a textured surface 43, imparting altered optical or electronic properties to the textured surface 43 by varying the strain present in second layer 42.

Experiments were performed using different transition metal dichalcogenide two-dimensional materials. First, the processes shown in FIGS. 1A-1F and 7C were performed, using a substrate 10 made of silicon, a SAM layer 30 of APTES, and a first layer 41 of aluminum oxide. In one set of experiments, the second layer 42 was monolayer molybdenum disulfide (MoS₂). In another set of experiments, the second layer 42 was monolayer tungsten diselenide (WSe₂).

FIG. 8 shows a photoluminescence (PL) map of the second layer 42 after the process has been completed. FIG. 8 illustrates enhanced photoluminescent intensity in the strained regions. While FIG. 8 was generated with a second layer 42 of MoS₂, the PL map for a second layer 42 of WSe₂ is similar.

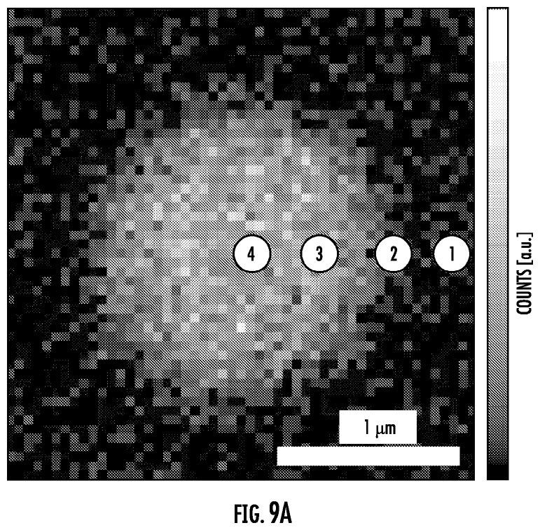

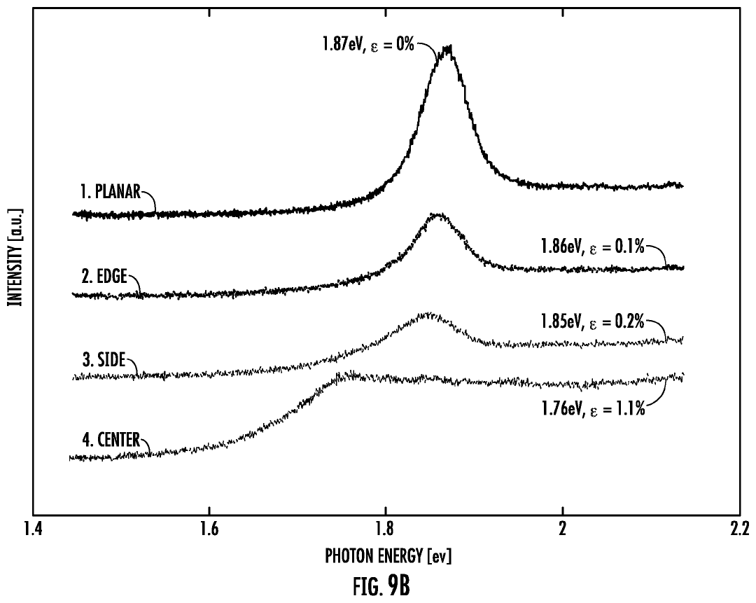

FIG. 9A shows an expanded view of one of the nonplanar nanostructures 50 that has a second layer 42 of MoS₂. In FIG. 9A, four locations are identified. These locations are defined as:
1: the planar portion of the second layer 42;
2: the edge of the nonplanar nanostructure 50;
3: the side of the nonplanar nanostructure 50; and
4: the center of the nonplanar nanostructure 50.

FIG. 9B shows the four characteristic PL spectra measured at the four locations identified in FIG. 9A. The four spectra are arbitrarily spaced apart on the vertical axis to better visualize the peak locations. These spectra show that the A exciton lowers in energy moving towards the center of the nonplanar nanostructure 50. This redshift is then correlated to the expected tensile strain in the material. The expected tensile strain is also shown in FIG. 9B.

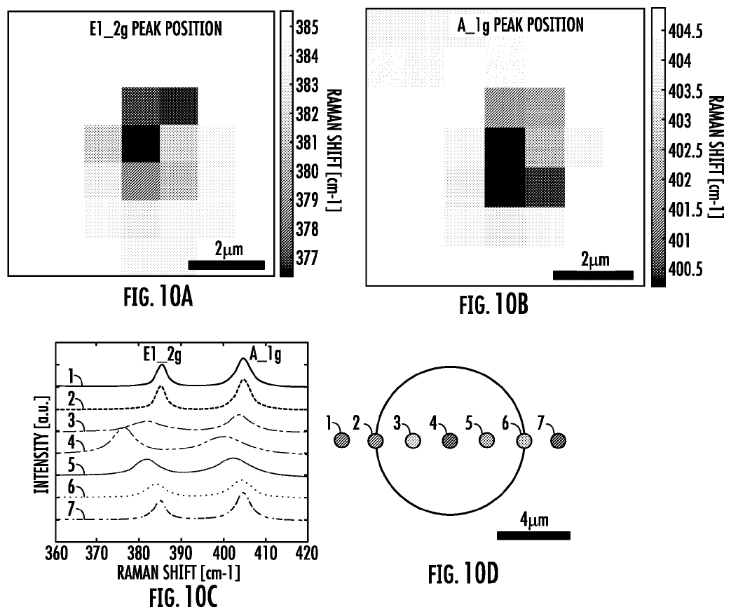

Raman spectroscopy was also used to validate the strain demonstrated in FIG. 9B. FIGS. 10A-10B show a Raman map for the two characteristic Raman peaks, where spectra were taken every 1 μm across the region of a blister. These figures show an increasing shift in Raman peaks as a function of increased strain toward the center of the nonplanar nanostructure 50. FIG. 10C shows Lorentzian fits to the Raman data taken at different points of the nanostructure (shown in FIG. 10D). The spectra are arbitrarily spaced apart on the vertical axis to better visualize the peak locations. FIG. 10C shows the increasing shift in Raman peaks as a function of increased strain toward the center of the nanostructure.

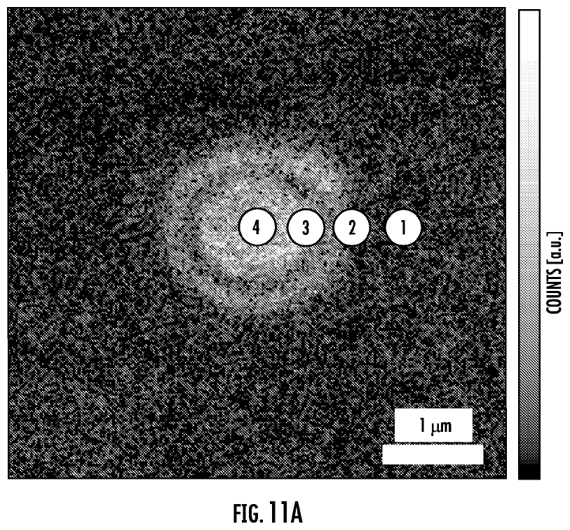

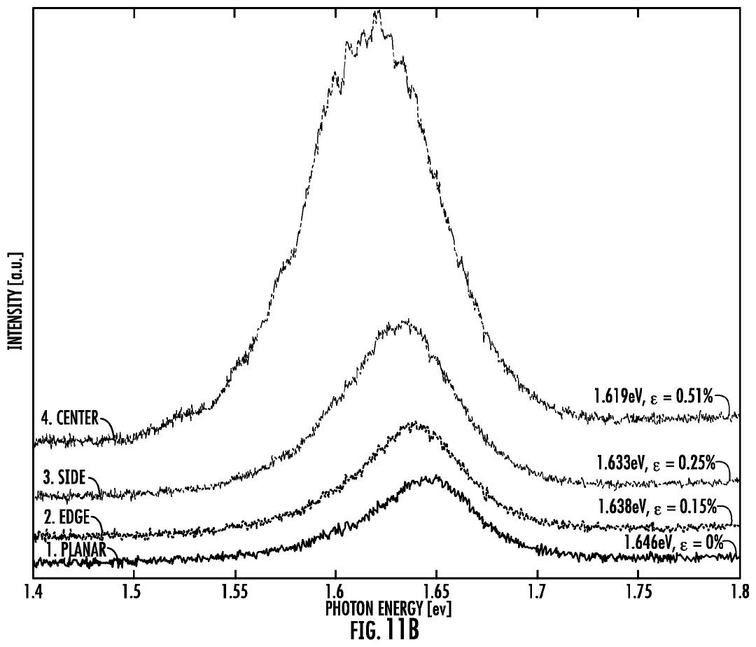

In a second set of experiments, the second layer 42 was WSe2. FIG. 11A shows an expanded view of one of the nonplanar nanostructures 50 that has a second layer 42 of WSe₂. In FIG. 11A, four locations are identified. FIG. 11B shows the four characteristic PL spectra measured at the four locations identified in FIG. 11A, arbitrarily spaced apart in the vertical axis. These spectra show that the A exciton lowers in energy moving towards the center of the nonplanar nanostructure 50. This redshift is then correlated to the expected tensile strain in the material. The expected tensile strain is also shown in FIG. 11B.

The process described in FIGS. 1A-1F and FIG. 7C is scalable and compatible with conventional fabrication techniques, allowing it to be readily implemented in practical device applications. Additionally, the process is compatible with many two-dimensional materials and may also be extended to other materials which would benefit from precise strain engineering.

Additionally, the design of the nanostructures may be defined before and/or after they are formed through further processing, for instance, through lithographic steps, such that topographies other than domes may be implemented. Additionally, the strained nanostructures formed may also be mechanically active in response to various external stimuli including electrostatic, mechanical, thermal, and piezoelectric, and others. This electromechanical feature allows for dynamic and reversible tuning of the strain, such that the intrinsic properties of the materials of interest may be actively modulated. If integrated with a closed-loop feedback system, this may further allow for deterministic fine-tuning of properties to achieve the desired functionalities. The strain engineering described herein allows diverse applications including in electronic devices (such as transistors) with improved mobilities, single photon sources that can be dynamically tuned, lasers, strain/pressure/mass sensors or other sensors, high-resolution nanoimaging, optical lenses, solar energy funnels, and optical and mechanical resonators.

While FIG. 7C and the accompanying description show that the two-dimensional material is the second layer 42, other embodiments are also possible. For example, in certain embodiments, the two-dimensional material may be directly grown, deposited for transferred onto the substrate 10. Thus, in the process shown in FIGS. 1A-1F, the film 40 may be a single layer and may be a two-dimensional material. Further, the film 40 may be multiple layers of a two-dimensional material. Alternatively, the film 40 may be other nanomaterials or thin films and may also include heterostructures of materials.

The present system and method have many advantages. The disclosed method enables novel opportunities for the fabrication of three-dimensional structures, nanogaps, and mechanically-active designs leading to diverse applications in optics, photonics, nanoelectronics, and electromechanical systems. Applications are diverse with significant impact, including in the development of optical and mechanical resonators, meta-surfaces, sensors, vacuum electronics, electromechanical switches, sensors and actuators. The present method may also provide an approach for structural texturing of nanomaterials and thin-films including two-dimensional layered materials to achieve strain engineering or other effects, as shown in FIG. 7C. Structural transformations in matter can lead to spatial modulation of their optical and electrical properties, yielding superior functionalities otherwise not available. Given that mechanically-active designs are possible, the resulting tunability can additionally be controlled dynamically in time. These designs, which are difficult to realize using conventional techniques, can enable new opportunities for novel devices.

A particular impact of the present method is in the development of technologies that require nanoscale gaps and mechanically-active structures. An example is in the field of micro/nanoelectromechanical systems (MEMS/NEMS) which has formed a multi-billion-dollar industry by developing diverse technologies including gyroscopes, accelerometers, and various types of sensors, switches, and actuators. To expand the prospects of this field, a foundational goal has been to improve the stability of electromechanical devices while also enabling their miniaturization. This is a fundamental challenge for conventional fabrication techniques, as the inevitable surface adhesive forces cause instability and even structural collapse. The present method addresses this challenge to develop much-desired, yet conventionally inaccessible, devices and systems for a multitude of emerging applications. As an example, FIGS. 7A-7B show two approaches to forming electromechanical devices which can be used as building blocks of sensors, actuators, and low-voltage switches. This method allows for scalable fabrication of these challenging designs while enabling stable operation and unprecedented miniaturization. Moreover, the process is compatible with current fabrication techniques such that it can be readily implemented without a need to build new infrastructures, increasing its value, and ensuring an immediate impact in NEMS/MEMS manufacturing.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1-41. (canceled)

42. A method of surface engineering, comprising:
applying a self-assembled molecular (SAM) layer to a portion of a surface of a substrate to produce an engineered surface;
applying a film over the engineered surface; and
applying energy to induce delamination of the film from the engineered surface so as to form a nonplanar nanostructure, wherein a gap exists between the nonplanar nanostructure and the substrate.

43. The method of claim 42, wherein molecules in the SAM layer have an anchoring group and a functional group; wherein the anchoring group allows assembly of the SAM layer on the surface of the substrate, and the functional group has a desired interaction with the film.

44. The method of claim 43, wherein the anchoring group is a silane group, an OH group, a COOH group or a thiol group and the functional group is an amine group, a hydroxyl group or a carboxyl group.

45. The method of claim 43, wherein the SAM layer comprises (3-Aminopropyl)triethoxysilane (APTES).

46. The method of claim 42, wherein the substrate comprises silicon.

47. The method of claim 42, wherein the substrate comprises an oxide, a nitride or a metallic material.

48. The method of claim 42, wherein the applied energy is light, heat or an electron beam.

49. The method of claim 42, wherein the nonplanar nanostructure is a dome shaped nanostructure, and the method further comprising:
applying a second mask to portions of the dome shaped nanostructure; and
removing the film in exposed regions so as to form a bridge structure suspended above the substrate.

50. The method of claim 49, wherein the bridge structure comprises a resonator.

51. The method of claim 42, wherein the film is a two-dimensional material.

52. The method of claim 42, wherein the delamination induces strain in the film.

53. The method of claim 52, wherein the strain changes optical and/or electrical properties of the film.

54. The method of claim 42, wherein the film is separated from the substrate by the gap and is free to move independent of the substrate; and further comprising applying an external stimulus to the film.

55. The method of claim 54, wherein the external stimulus is actively modulated.

56. The method of claim 54, wherein the external stimulus is electrostatic, mechanical, thermal, or piezoelectric.

57. The method of claim 42, wherein the nonplanar nanostructure is subject to further processing.

58. The method of claim 42, wherein the film comprises a plurality of layers.

59. The method of claim 58, wherein one of the plurality of layers comprises a metal.

60. The method of claim 58, wherein a first of the plurality of layers comprises an oxide and a second of the plurality of layers comprises a two dimensional material.
